(19) United States
(12) Patent Application Publication
(10) Pub. No.: US 2015/0015234 A1
(43) Pub. Date: Jan. 15, 2015

(54) CONTACT VOLTAGE DETECTION SYSTEM AND METHOD

(71) Applicant: Cintas Corporation, Cincinnati, OH (US)

(72) Inventors: Eric Ayanegui, Richmond, TX (US); Willie A. Isaacs, Huber Heights, OH (US); Dudley L. Rogers, III, Concord, NC (US); Gardner Sorrell, Middletown, OH (US)

(73) Assignee: CINTAS CORPORATION, Cincinnati, OH (US)

(21) Appl. No.: 14/327,669

(22) Filed: Jul. 10, 2014

Related U.S. Application Data
(60) Provisional application No. 61/845,027, filed on Jul. 11, 2013.

(51) Int. Cl. G01R 19/155; G01R 19/00

(52) U.S. Cl. CPC G01R 19/155; G01R 19/0084
USPC 324/76.11

(57) ABSTRACT

An electrical safety system and associated method may be used on an electrical enclosure containing phase to phase and phase to ground electricity. The system includes a volt meter having a probe and a receptacle having a number of ports adapted to receive the probe of the volt meter. The receptacle is mounted to a panel, cabinet or enclosure having at least one conducting wire therein. The method allows a worker to use a contact voltage detector to check for the presence or absence of voltage inside the closed electrical panel.

### Cross Reference to Related Application

This application claims the benefit of U.S. Provisional Patent Application Ser. No. 61/845,027, filed on Jul. 11, 2013, and herein incorporated by reference in its entirety.

### BACKGROUND OF THE INVENTION

This invention generally relates to systems and methods for safely determining if electrical power is removed from an electrically powered apparatus, so that the electrically powered apparatus may be safely serviced. More specifically, this invention relates to systems and methods which are accessible from the outside of the electrically powered apparatus to protect an operator of the electrically powered apparatus from the electrical power connected to the device.

High voltage machinery can pose a danger to an operator of the machinery during a malfunction, service or adjustment of the machinery. One common danger by which the operator can be injured due to the electrical power to the machine not being properly turned off is the failure of currently available electrical power indication safety devices on the machinery. These safety devices may give a false indication of the electrical power being off or they may malfunction. A second common danger is inexperience of the operator in determining if the electrical power is on or off in situations where the safety device fails and in situations where the machinery does not have an electrical power indicator. One solution to such dangers is to not allow the operator to work on the machinery until electrical power shutdown is verified by a qualified electrician. Waiting for a qualified electrician can incur additional operating costs, due to down time and the labor of the electrician.

To ensure safety during servicing of electrical systems and circuits which carry high voltages, a “lockout/tagout” procedure is typically followed. A circuit breaker or ON/OFF switch that delivers power to the circuit to be serviced is opened or disengaged to disconnect electrical power from the circuit, and the breaker is physically locked into the opened or disengaged position using a padlock or other device (the “lockout”). Additionally, the servicing technician affixes a tag to the physically locked breaker that provides information such as the technician's identity and contact information, service authorization information, and the like (the “tagout”).

The lockout/tagout procedure greatly reduces the possibility of human error causing inadvertent application of power to the circuit under service. However, safety can be compromised even when the lockout/tagout procedure is properly followed, due to various potential sources of dangerously high voltages in the isolated circuit. For example, potential unexpected sources of energy include line capacitance, bypass capacitors, or power factor correction banks. Potential unexpected sources of energy also include standby power generators, motor back-EMF, or human operation of an associated switch. Moreover, power ON/OFF switches and circuit breakers are not immune to failure, and the locked out breaker could potentially still be transmitting power.

These procedures apply to products that are often known as convenience interfaces or panel interfaces. A convenience interface provides a convenient method for personnel to access devices that reside inside a cabinet or an enclosure without opening the enclosure door.

Industrial and commercial facilities typically have electrical cabinets providing access to line voltages. The electrical cabinets remain closed except when access is needed by maintenance personnel. When maintenance personnel open the electrical cabinets there is the risk of electrical accidents causing injury or death. Various safety measures can be taken and protocols followed to reduce the risk of electrical accidents but these measures may not always be taken and protocols followed due to the reduction in productivity associated with doing so. When these measures are taken and protocols are followed there may be a reduction in productivity.

The National Fire Protection Association (NFPA) recently published a Standard for Electrical Safety in the Workplace, and that document generated essential changes in the way both electrical and mechanical maintenance is performed in today's industrial and commercial facilities. NFPA 70E specifically sets forth standards for electrical safety in the workplace. Compliance with such standards reduces injuries and deaths, but in a manner which often reduces productivity experienced prior to NFPA 70E. For example, service technicians often don personal protection equipment (PPE) when accessing electrical enclosures, cabinets and other equipment. Unfortunately, the use of PPE is time consuming, cumbersome and inefficient.

Non-contact voltage detectors (NCVD) typically in the form of a test pen are a well-known means to attempt to determine the absence or presence of voltage. NCVD's are disclosed in U.S. Patent Publication Nos. 2012/0098522 and 2013/0127440, each hereby incorporated by reference entirely. In a NCVD, changes in an electric field associated with the presence of an AC voltage may be detected capacitively without direct contact between the test pen or instrument and the potentially voltage carrying circuit, conductor, wire or other device. But, because of the possibility of false negatives, meaning that the voltage tester falsely indicates that there is not a voltage when there actually is, NCVD's have not been considered a reliable means in determining electrical isolation. NCVD relies on capacitance and external factors not related to the tested conductor may also affect the voltage reading which creates a potential false negative situation when voltage is present.

There are numerous other problems associated with present NCVD designs. A NCVD must have a completed circuit between the live conductor, conductor insulation, NCVD tip, NCVD circuit, NCVD case, worker and ground. Presently NCVD systems available do not know the state of the live conductor or the insulation. The only remaining unknown is the worker or the NCVD connection to ground. Thus, the NCVD may become more reliable if these components of the circuit could also become a known.

When a handheld NCVD is positioned next to an energized conductor, two capacitive circuits are created. A smaller capacitance exists between the energized conductor and the NCVD, while a larger capacitance exists between the NCVD through the electrical worker's body to ground. If voltage is applied across a capacitor, then the voltage drop across a small capacitor is bigger than the voltage drop across a larger capacitor. By comparing both of these voltages using a specific non-contact voltage detector circuit, the NCVD decides if the conductor is energized. However, because this circuit is somewhat sensitive, other electrical energy within an enclosure will change the effective capacitance and ultimately the operation and reliability of NCVD. A false-negative reading is the worst case scenario when stray parasitic capacitance from other energized components and/or to ground change the overall capacitance of the circuit in question.

Another way to test for voltages is to use a hardwired voltage indicator. Voltage indicators installed by qualified electricians are hardwired to the main power disconnect and earth ground. Installation is simple because a phase-neutral high impedance voltage detection circuit on each phase senses and illuminates AC/DC voltage. Two issues with hardwired voltage indicators are that (1) it is impractical to verify the voltage indicator to another independent voltage source as attempting to do so adds complexity and reduces reliability and (2) since the voltage indicator's sole purpose is to indicate voltage, any electrical connection issues between the source voltage and the voltage indicator increases the chance of a false negative voltage reading.

Therefore, it is apparent that a more reliable and convenient system and method for testing voltage in machinery or circuits is needed for compliance with NFPA 70E.

### SUMMARY OF THE INVENTION

These and other shortcomings with prior systems and methods have been addressed with this invention. In one embodiment, this invention is an electrical safety system used on an electrical enclosure containing phase to phase and phase to ground electricity. The system may include a portable or handheld volt meter having one or more probes and a receptacle having a front surface, a mounting body and a rear surface. The receptacle has a number of ports each adapted to receive a probe of the volt meter. The receptacle is mounted to a panel or door of a cabinet or enclosure having at least one conducting wire therein as part of a circuit. The wire has an exposed section at a location from an outside face of the front of the receptacle, such that the depth is enough to prevent passing of electrical current, yet close enough to allow the probe of the volt meter inserted into one of the receptacle ports to contact the wire and be activated when electrical current is present in the wire. The device allows a worker to use a contact voltage detector to check for the presence or absence of voltage inside the closed electrical panel without opening the panel or enclosure.

In one embodiment, this invention may include the receptacle, the portable volt meter, a voltage indicator and a number of fuses and holders. These components, with the exception of the portable volt meter and associated probes, are mounted to the panel or within the electrical enclosure.

The receptacle may have a front side and an opposite back side configured to hold one or more wires in a fixed position within the closed electrical panel, and the ports in the front side allow for direct contact with a probe of the contact voltage detector for testing with the contact voltage detector. The particular configuration of the receptacle may vary, but according to various embodiments of this invention the receptacle is mounted to the exterior or deadfront panel of the enclosure or cabinet and has one or more ports for the direct contact of the volt meter probe to one of the conductors or wires within the enclosure. This is distinguishable from a proximity or non-contact capacitive voltage detection (NCVD) operation in which the probe does not contact the wires or conductors in the cabinet to measure voltage.

The hardwired voltage indicator mounted on the panel is an optional component of this invention. One aspect of the invention is a deadfront (i.e., exterior panel) contact (as opposed to non-contact or proximity) testing for live-dead-live, phases to phase and phase to ground voltage testing. Another aspect is the overall procedure or protocol for compliance with NFPA 70E utilizing such a device with a live-dead-live testing protocol. In such a protocol, the operational capabilities of the portable volt meter are tested on a live electrical source. If operational, the volt meter is then used on the electrical enclosure via the receptacle to verify that the electricity in the enclosure is off (i.e., dead). Finally, the portable volt meter is once again tested on a live electrical source to verify its continuing operational capabilities. If each step of the protocol is successful, the electrical cabinet or enclosure maybe opened and accessed by a technician for maintenance, repair or the like in compliance with the NFPA 70E. The live-dead-live protocol utilizing the receptacle of this invention may be accomplished without the need for the technician to don personal protection equipment (PPE), the use of which has proven to be both cumbersome and inefficient to satisfy the testing requirements, because the cabinet or enclosure remains closed during the test protocol.

### BRIEF DESCRIPTION OF THE DRAWINGS

The above-mentioned and other features and advantages of this invention, and the manner of attaining them, will become more apparent and the invention itself will be better understood by reference to the following description of embodiments of the invention taken in conjunction with the accompanying drawings, wherein:

FIG. 1 is a perspective view of an exemplary electrical enclosure with components of one embodiment of this invention mounted on a front panel thereof;

FIG. 2 is an enlarged perspective view of the components of FIG. 1 prior to testing;

FIG. 3 is a view similar to FIG. 2 during testing;

FIG. 4 is an enlarged view in partial cross-section showing the contact voltage testing of an electrical circuit within the enclosure according to one aspect of this invention;

FIG. 5 is a flow chart showing one testing method protocol according to this invention; and

FIG. 6 is a view of an alternative embodiment of components of this invention mounted on the front panel of an enclosure.

### DETAILED DESCRIPTION OF THE INVENTION

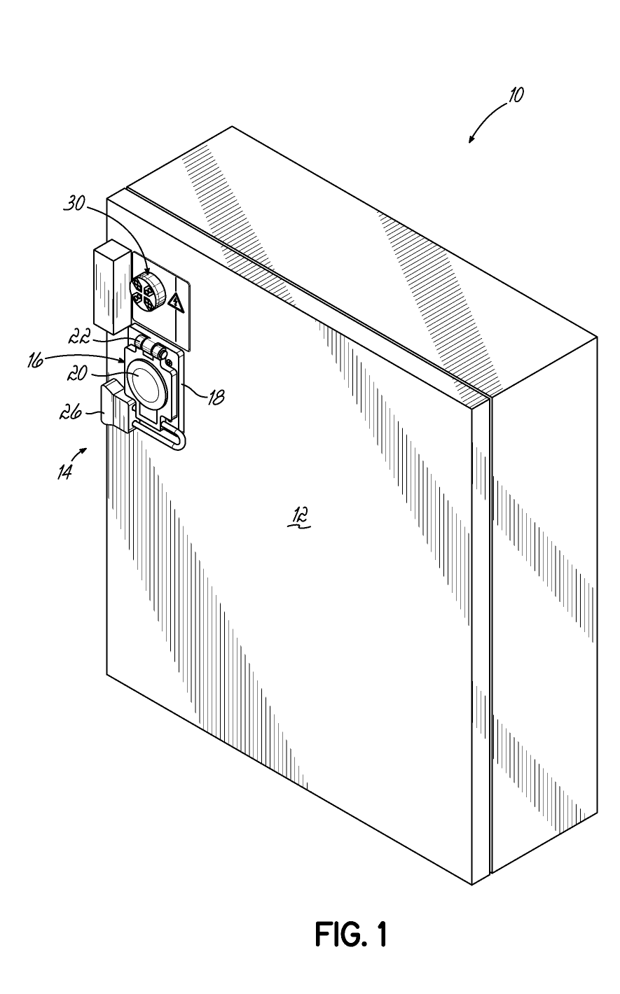

Referring to FIG. 1, an exemplary electrical enclosure 10 is shown in the form of a generally parallelepiped or cuboid cabinet. The enclosure has a front panel 12 which may be opened to allow for access to the interior of the enclosure 10 for a technician or service personnel. It should be understood that the enclosure 10 and associated panel 12 of FIG. 1 are exemplary only and this invention is applicable to a wide variety of enclosures and panels.

These enclosures 10 can include: (1) control devices with data ports, (2) network access ports, (3) human interface ports such as for a computer mouse or keyboard, (4) various I/O devices, (5) data storage devices, and (6) programmable devices.

As shown in various detail in FIGS. 1-4, the contact voltage detection system 14 and associated method according to one embodiment of this invention include a receptacle 16 mounted on the panel 12 of the enclosure 10 for access by a technician or other support personnel. In one embodiment, the receptacle 16 may be a Granger part #4UFP5 and Levaton manufacture part #67W76 (cover and receptacle). The receptacle includes a face plate mounting body 18 on the panel 12 of the enclosure 10 and a cover 20 pivotally connected to the face plate 18 via a hinge 22 for selectively opening and closing the cover 20 to expose and conceal, respectively, a number of ports 24 provided in the face plate 18. The cover 20 may be secured in a closed position as shown in FIG. 1 via a lock 26 securely coupled to a hasp arrangement 28 on the face plate 18 and cover 20. The cover 20 is typically kept closed and locked unless testing is required. The receptacle 16 according to various embodiments of this invention is NEMA rated, waterproof and has a lockable cover as previously discussed.

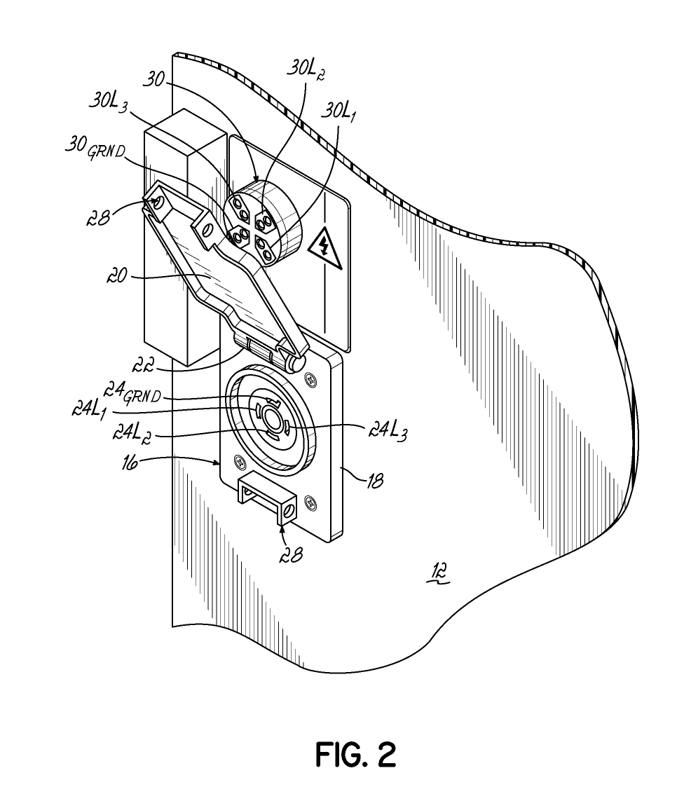

As shown particularly in FIGS. 2, 3 and 4, the face plate 18 of the receptacle 16 includes four ports identified as 24L₁, 24L₂, 24L₃ and 24GRND in one embodiment of this invention.

Another component according to one aspect of this invention is a multi-line indicator 30 mounted on the panel 12 of the enclosure 10. The indicator 30 is tied directly to the incoming power without fuses and is used in conjunction with the receptacle 16 in an effort to eliminate the possibility of a false negative reading relative to voltage active in the enclosure 10. The indicator 30 allows for verification visually that voltage is or is not present in the line independent of the receptacle 16.

The indicator 30 according to one embodiment of this invention includes four indicator signals 30L₁, 30L₂, 30L₃ and 30GRND, each of which includes dual redundant indicator lights 32 which when lit indicate active voltage in the associated line 34L₁, 34L₂, 34L₃ and 34GRND of the electrical enclosure 10. In one embodiment of this invention, the indicator 30 may be a Grace Engineering part *Voltage Vision R-3W voltage indicator or similar device. The indicator 30 also may be as disclosed in U.S. Pat. No. 6,703,938 or U.S. Patent Application No. 2007/0132458, each incorporated by reference entirely herein.

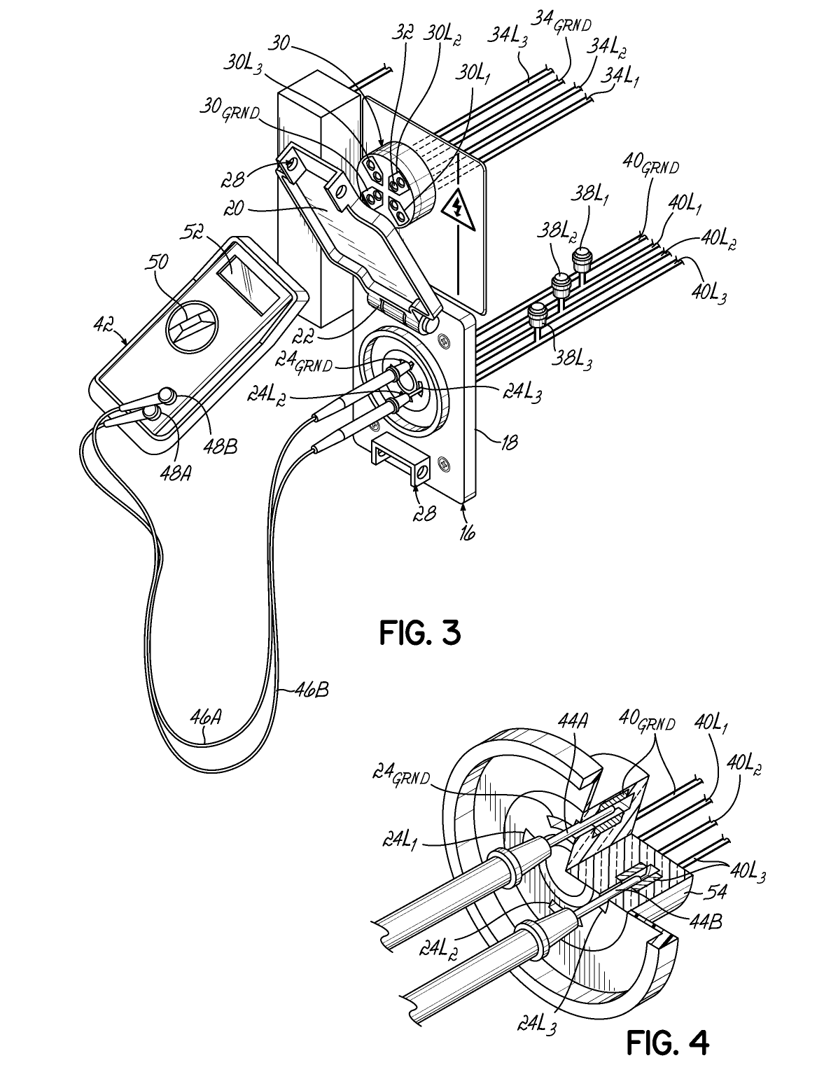

Referring particularly to FIG. 3, an inline fuse holder 38L₁, 38L₂ and 38L₃ and associated fuse (not shown) contained therein is added to each of the lines 40L₁, 40L₂, 40L₃ connected to the respective port 24L₁, 24L₂ and 24L₃ on the receptacle 16. In one embodiment of this invention, each inline fuse holder 38 may be a Granger part #1CW08 and the fuse mounted therein may be a 3/10 amp, 300 volt rated fuse, Granger part #1CK41. The inline fuse and holder 38 prevent the receptacle 16 and ports 24 from being used for almost any purpose other than testing.

As shown in FIG. 3, each of the ports on the receptacle and the indicator signals on the indicator include respective conductors, electrical wires or lines connected to and associated therewith as shown in FIG. 3. The lines 40 of the receptacle 16 are in parallel with the lines 34 associated with the indicator 30.

Another component on the various embodiments of this invention is shown in FIG. 3 which includes a portable and/or handheld volt meter 42. The volt meter 42 as is commonly understood includes two probes 44A, 44B each connected to a respective line 46A, 46B and coupled to an appropriate jack 48A, 48B on the volt meter 42. One probe 44A is typically a measuring lead and may be colored red while the other probe 44B is a reference or a ground lead and is often colored black according to convention. The volt meter 42 may include a dial selector 50 for selectively adjusting the volt meter 42 to the appropriate function such as DC volts, AC volts, AC amps or the like. The volt meter 42 may also include a display 52 to indicate the volts, amps or other measurement detected by the probes 44A, 44B and may include an audible notification component.

Referring to FIG. 4, a partially sectioned receptacle 16 according to one embodiment of this invention is shown in which the probes 44A, 44B when inserted into selected ports 24 of the receptacle i6 are in direct electrical contact with the associated line 40 connected to that port 24 of the receptacle i6. A receptacle hub 54 extends rearwardly on a rear surface of the receptacle i6. The ports 24 of the receptacle i6 are in communication with the conductors or wires 40L₁, 40L₂, 40L₃ and 40GRND of the L₁, L₂, L₃ and ground lines connected to the receptacle 16 to allow for direct contact between the probe 44 inserted through the port 24 and the associated line 40 as shown in FIG. 4.

FIGS. 2-4 illustrate one embodiment of a pass through receptacle i6 as used in a particular environment. The receptacle i6 allows workers using a contact portable voltage meter 42 to check for the presence or absence of voltage inside a closed electrical cabinet 10. The pass through receptacle 16 positions one or more electrical conductors 40 close enough to the outside of the electrical panel 12 so that a probe of a portable voltage meter 42 can detect via direct contact with each conductor 40 while the cabinet 10 is closed to indicate the presence or absence of voltage. Thus, in this manner when voltage is present on a wire 40 within the cabinet 10, a worker can receive an indication that voltage is present without opening the panel 12 and without coming into contact with the energized conductor(s) 40 present within the electrical cabinet 10. Because the electrical cabinet 10 need not be opened there is a significant potential savings in productivity of the worker because the worker does not need to go through the time-consuming safety procedures which should be followed (i.e., donning PPE, erecting a flash barrier, etc.) if the energized electrical cabinet is opened.

FIG. 1 illustrates one embodiment of a system 14 that allows for reliable determination of whether or not voltage is present. The contact voltage portal receptacle 16 is installed on the grounded metallic electrical panel or front door 12 of the cabinet enclosure 10. When a contact voltage portal receptacle 16 is installed into the grounded metallic or non-metallic electrical panel 12, a scenario is created whereby voltage present in a conductor 40 is now able to be directly measured via contact from a volt meter probe 44. Thus, when the contact voltage detector (CVD) handheld, portable volt meter 42 probe 44 is placed into contact with a conductor 40 inside the cabinet 10 via the receptacle 16, the electrical worker is assured via an audible and/or visual alert on the volt meter 42 that the completed circuit is either live or dead.

The receptacle 16 has an assembly which has a front side shown which includes a plurality of ports 24. The receptacle 16 may be formed of plastic or other non-metallic material. As shown in FIG. 4, the receptacle 16 also has a back side with a hub 54. Although a single part receptacle 16 is shown, this invention contemplates that the receptacle 16 may alternatively be a two or more part assembly. The receptacle 16 allows the voltage on three wires (each of which may be 18-14 AWG) L₁, L₂, L₃ to be checked with a contact voltage meter 42 to see if there is hazardous voltage on any of the three wires. The receptacle 16 does this by making sure the wires L₁, L₂, L₃ are accessible through the front panel 12 at the correct position so a contact voltage meter probe 44 can be inserted into the front of the receptacle 16 and thru the ports 24 to verify the presence of voltage in the wire(s) 40.

One or more of the lines L₁, L₂, L₃ may carry substantial or even lethal d.c. or a.c. electrical energy potentials due to charged capacitances in the load, undischarged power factor correction banks, standby power generators, motor back-EMF voltages, power sources that inadvertently remain energized and/or connected to the circuit through human error or mechanical failure, or the like. These electrical energy potentials may exist between the lines L₁, L₂, L₃ and/or between one or more of the lines L₁, L₂, L₃ and the ground potential GRND. The electrical safety monitoring system 14 of this invention monitors the lines L₁, L₂, L₃ and the ground potential GRND to detect hazardous energy potentials.

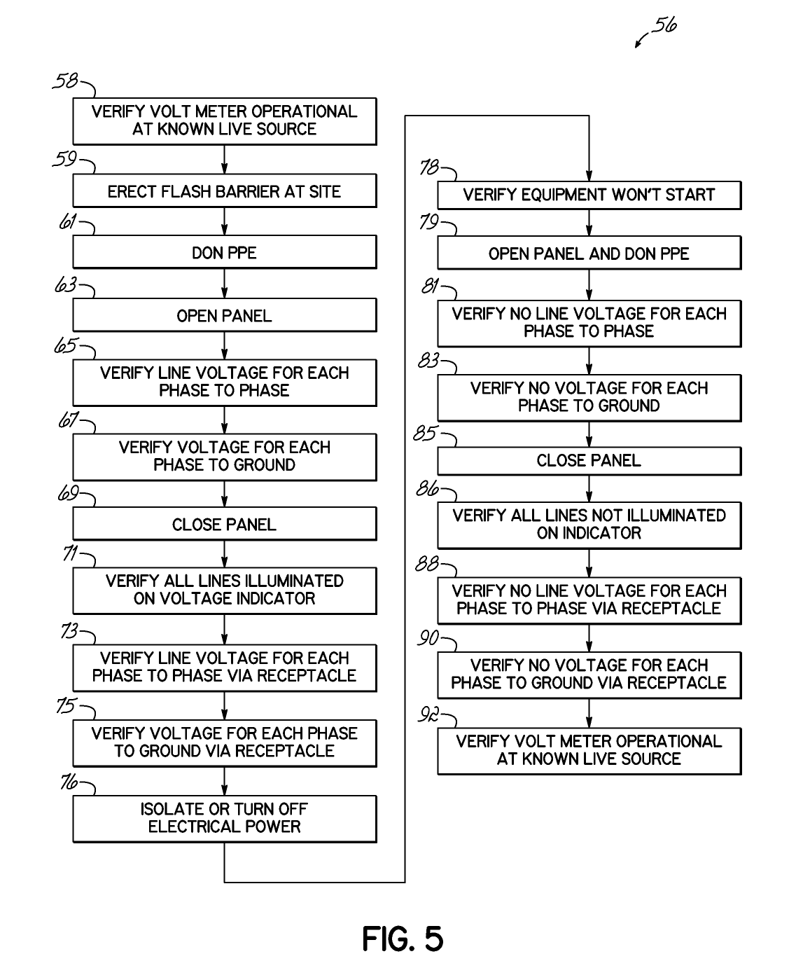

Referring to FIG. 5, embodiments of one or more testing methods 56 utilizing the system 14 according to this invention are shown. The testing method or protocol 56 shown in FIG. 5 may include the lockout/tagout protocol according to one embodiment of this invention. Various steps within the method 56 shown in FIG. 5 may be omitted once the system 14 installation is verified as operational and compliant with all applicable safety regulations and requirements. As shown in FIG. 5, an initial step 58 in one method 56 according to this invention is the verification of the operation of the volt meter 42 at a known live source.

A next step 59 for the initial verification and installation of the system 14 is to erect a flash barrier at the site surrounding the electrical enclosure 10. A four foot arc flash barrier is often recommended. Next steps include a service technician donning PPE 61 and then opening the enclosure and panel 63 mounted thereon. The service technician then verifies 65 the line voltage for each phase utilizing the volt meter 42 with direct contact to the associated lines L₁, L₂, L₃. A service technician then verifies 67 the voltage for each phase to ground in a similar manner. Presumably these steps result in the volt meter 42 reading a positive voltage active within the enclosure 10 for the associated lines. Once these steps are completed, the panel 12 on the enclosure 10 is closed 69 and then the service technician verifies 71 that all lights associated with lines L₁, L₂, L₃ are illuminated on the voltage indicator 30 confirming active voltage in the lines and proper operation of the indicator 30.

A service technician then verifies 73 the line voltage for each phase to phase utilizing the probes 44 on the volt meter 42 and the ports 24 on the receptacle 16. Next, the technician verifies 75 the voltage for each phase to ground via the receptacle 16 in a similar manner. These readings will likewise indicate active electricity on the lines L₁, L₂, L₃ and proper operation of the receptacle 16 and volt meter 42.

The technician then isolates and turns off the electrical power 76 to the enclosure 10 in preparation for servicing the system. A documented lockout/tagout procedure may be followed to de-energize the equipment. The power down or isolation step 76 may include disconnecting the main electrical power isolating or disconnecting the enclosure 10 and isolating or disconnecting any compression air valve to bring equipment to a zero stage associated within the electrical enclosure 10. The technician then verifies 78 that the equipment associated with the electrical enclosure 10 will not operate or start.

The service technician then may open 79 the panel 12 on the cabinet or enclosure 10 while donning the PPE for protection. The service technician then verifies 81 that line voltage L₁, L₂, L₃ for each phase to phase has been shut off utilizing the volt meter 42.

The reading on the volt meter 42 at this step may show a nominal amount of voltage which is often referred to as a phantom voltage transmitted from adjacent electrical lines and is commonly a fraction of the line voltage measured prior to electrical power isolation. Next, voltage for each phase to ground is likewise checked 83 while the panel 12 is open. The panel 12 is then closed 85 and the technician verifies 86 that the indicator 30 is not illuminated and that each of the signals 32 is off. The technician then verifies 88 that the line voltage for each phase to phase is off utilizing the ports 24 on the receptacle 16 with the volt meter 42. Here again, the reading on the volt meter 42 may show a nominal amount which is the phantom voltage transmitted from adjacent electrical lines. The technician also verifies 90 the voltage for each phase to ground is isolated or off with the exception of any phantom voltage reading.

It is important to note that the probes 44 of the volt meter 42 are in direct contact with each line or phase associated with the various ports 24 of the receptacle 16 during steps 88 and 90 thereby providing for direct or contact voltage detection through the dead front of the panel 12 on the closure 10.

If the indicator 30 and the measurements from the receptacle ports 24 each indicate that the electrical system is isolated, a final step in the testing protocol according to one embodiment of this invention is to once again verify 92 that the volt meter 42 is operational at a known live source such as a nearby electrical outlet or the like.

The various methods and steps described herein and shown in FIG. 5 include various steps which may be only performed upon initial installation and verification of the system 14 on the electrical enclosure 10 and those steps are indicated as odd numbed reference numerals herein (i.e., 59, 61, 63, 65, etc.) and in FIG. 5. As such, the odd reference numeral steps of FIG. 5 may be omitted once the initial installation of the system is verified and subsequent testing prior to servicing of the electrical enclosure 10 may be performed with only the even numbered reference numerals in compliance with NFPA 70E and according to various embodiments of this invention. Moreover, the even numbered steps in FIG. 5 comprise one embodiment of this invention and additional embodiments may include less than all of those steps and/or additional steps such as some or all of the odd numbered steps according to this invention. In one aspect, this invention may be employed to retrofit an existing electrical enclosure installation and in another aspect this invention may be included with a new electrical enclosure installation.

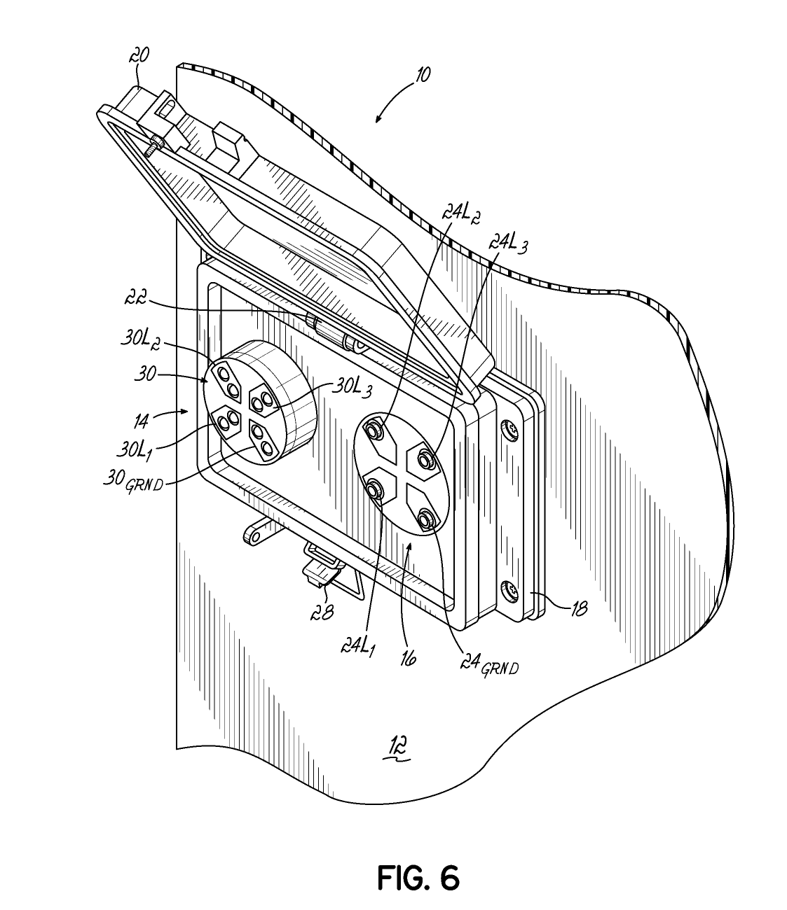

An alternative to the embodiment of this invention as presented in FIGS. 1-4 is shown in FIG. 6. The embodiment of FIG. 6 provides the same functionality as the embodiment of FIGS. 1-4 with a different aesthetic presentation. As such, the same reference numerals utilized with respect to the embodiment of FIGS. 1-4 are used for the same or similar components in FIG. 6. Both the indicator 30 and the receptacle 16 are covered by the cover 20 which may be secured by the lock 26 (not shown in FIG. 6). The ports 24L₁, 24L₂, 24L₃ and 24GRND provided in the receptacle 16 in the embodiment of FIG. 6 each may be smaller than those of the embodiment of FIGS. 1-4 so as to inhibit, inadvertent or otherwise, the insertion of an item other than the probes 44A, 44B of the volt meter 42. Nevertheless, the receptacle 16 and associated ports 24L₁, 24L₂, 24L₃ and 24GRND of the embodiment of FIG. 6 provide for direct, physical contacted with the associated lines 40L₁, 40L₂, 40L₃ and 40GRND (not shown in FIG. 6) similar to the embodiment of FIGS. 1-4.

From the above disclosure of the general principles of this invention and the preceding detailed description of at least one embodiment, those skilled in the art will readily comprehend the various modifications to which this invention is susceptible. Therefore, we desire to be limited only by the scope of the following claims and equivalents thereof.

We claim:

1. An electrical safety monitoring system for testing voltage being carried in lines L₁, L₂, L₃ and GRND of a three-phase connection within an enclosure having a panel, the system comprising;
a receptacle mounted to the panel of the enclosure, each of the lines L₁, L₂, L₃ and GRND being coupled to the receptacle;
a first, a second, a third and a fourth port in the receptacle being associated with the L₁, L₂, L₃ and GRND lines, respectively, to provide access to the associated line from an exterior of the enclosure via the respective port; and
a volt meter having at least two probes selectively inserted into the receptacle and through any two of the first, second, third and fourth ports from outside of the enclosure for direct electrical connection with two of the lines L₁, L₂, L₃ and GRND associated with the respective ports to measure voltage therein and thereby provide an indication to a user of active voltage within the three-phase connection in the enclosure and without opening the enclosure.

2. The safety monitoring system of claim 1 further comprising:
a cover for selectively covering the ports in the receptacle from an exterior of the enclosure.

3. The safety monitoring system of claim 2 further comprising:
a lock selectively coupled to the cover to secure the cover in a closed position relative to the ports of the receptacle.

4. The safety monitoring system of claim 1 further comprising:
an indicator mounted on an exterior of the enclosure and electrically coupled to the three-phase connection within the enclosure to thereby provide an indication of voltage being carried therein independent of the volt meter.

5. The safety monitoring system of claim 4 wherein the indicator is electrically coupled to lines different from and parallel with lines L₁, L₂ and L₃.

6. The safety monitoring system of claim 1 further comprising:
a first, a second and a third in-line fuse holder on lines L₁, L₂ and L₃, respectively, within the enclosure.

7. An electrical safety monitoring system for testing voltage being carried in lines L₁, L₂, L₃, and GRND of a three-phase connection within an enclosure having a panel, the system comprising;
a receptacle mounted to the panel of the enclosure, each of the lines L₁, L₂, L₃ and GRND being coupled to the receptacle;
a first, a second, a third and a fourth port in the receptacle being associated with the L₁, L₂, L₃ and GRND lines, respectively, to provide access to the associated line from an exterior of the enclosure via the respective port;
a cover for selectively covering the ports in the receptacle from an exterior of the enclosure;
a lock selectively coupled to the cover to secure the cover in a closed position relative to the ports of the receptacle;
a first, a second and a third in-line fuse holder on lines L₁, L₂ and L₃, respectively, within the enclosure;
a volt meter having at least two probes selectively inserted into the receptacle and through any two of the first, second, third and fourth ports from outside of the enclosure for direct electrical connection with two of the lines L₁, L₂, L₃ and GRND associated with the respective ports to measure voltage therein and thereby provide an indication to a user of active voltage within the three-phase connection in the enclosure and without opening the enclosure;
an indicator mounted on an exterior of the enclosure and electrically coupled to the three-phase connection within the enclosure to thereby provide an indication of voltage being carried therein independent of the volt meter;
wherein the indicator is electrically coupled to lines different from and parallel with lines L₁, L₂ and L₃.

8. An improvement to an electrical safety monitoring system having hardwired L₁, L₂, L₃ and GRND three-phase line connections within an enclosure and a plurality of indicators on an exterior surface of the enclosure for communicating presence of voltage between any of the line connections, the improvement comprising:
a receptacle mounted to the enclosure, each of the lines L₁, L₂, L₃ and GRND being coupled to the receptacle;
a first, a second, a third and a fourth port in the receptacle being associated with the L₁, L₂, L₃ and GRND lines, respectively, to provide access to the associated line from an exterior of the enclosure via the respective port; and
a volt meter having at least two probes selectively inserted into the receptacle and through any two of the first, second, third and fourth ports from outside of the enclosure for direct electrical connection with two of the lines L₁, L₂, L₃ and GRND associated with the respective ports to measure voltage therein and thereby provide an indication to a user of active voltage within the three-phase connection in the enclosure and without opening the enclosure.

9. The improvement of claim 8 further comprising:
a first, a second and a third in-line fuse holder on lines L₁, L₂ and L₃, respectively, within the enclosure.

10. A method for providing electrical safety monitoring for voltage within an enclosure having an exterior panel and L₁, L₂, L₃ and a GRND three-phase lines forming a connection within the enclosure, the method comprising the steps of:
mounting an electrical safety receptacle on the exterior panel of the enclosure, the receptacle having a first, a second, a third and a fourth port being associated with the L₁, L₂, L₃ and GRND lines, respectively, to provide access to the associated line from an exterior of the enclosure via the respective port;
inserting a first and a second probe connected to a volt meter into the receptacle and through any two of the first, second, third and fourth ports from outside of the enclosure; and
contacting the first and second probes and two of the lines L₁, L₂, L₃ and GRND associated with the respective ports to establish a direct electrical connection to measure voltage in the two lines and thereby provide an indication to a user of active voltage within the three-phase lines in the enclosure.

11. The method of claim 10 wherein the indication of active voltage is provided without opening the enclosure.

12. The method of claim ii wherein the first and second probe are each in direct physical contact with one of the lines L₁, L₂, L₃ and GRND as a result of the inserting step.

13. The method of claim 10 further comprising:
installing a first, a second and a third in-line fuse holder on lines L₁, L₂ and L₃, respectively, within the enclosure.

14. The method of claim 10 further comprising:
monitoring an indicator mounted on an exterior of the enclosure and electrically coupled to the three-phase connection within the enclosure to thereby provide an indication of voltage being carried therein independent of the volt meter.

15. The method of claim 10 further comprising:
verifying the operation of the volt meter at an electrical source other than any in the enclosure.

16. The method of claim 15 wherein the verifying step is performed at least one of prior to and subsequent to the inserting step.

17. The method of claim 10 performed in compliance with NFPA 70E and without the user donning PPE.

18. The method of claim 10 wherein the inserting step further comprises:
verifying voltage for each phase to phase combination of the L₁, L₂ and L₃ lines; and
verifying voltage for each phase to ground combination of the L₁, L₂, L₃ and GRND lines.

19. The method of claim 10 further comprising:
isolating electrical power to the enclosure prior to the inserting step; and thereafter
checking that any equipment electrically driven by the enclosure is non-operational.

20. The method of claim 16 further comprising:
verifying voltage for each phase to phase combination of the L₁, L₂ and L₃ lines;
verifying voltage for each phase to ground combination of the L₁, L₂, L₃ and GRND lines;
isolating electrical power to the enclosure prior to the inserting step; and thereafter
checking that any equipment electrically driven by the enclosure is non-operational.

21. A method for providing electrical safety monitoring for voltage in compliance with NFPA 70E for an enclosure having an exterior panel and L₁, L₂, L₃ and a GRND three-phase lines forming a connection within the enclosure, the method comprising the steps of:
mounting an electrical safety receptacle on the exterior panel of the enclosure, the receptacle having a first, a second, a third and a fourth port being associated with the L₁, L₂, L₃ and GRND lines, respectively, to provide access to the associated line from an exterior of the enclosure via the respective port;
installing a first, a second and a third in-line fuse holder on lines L₁, L₂ and L₃, respectively, within the enclosure;
isolating electrical power to the enclosure;
checking that any equipment electrically driven by the enclosure is non-operational;
subsequent to the isolating and checking steps, inserting a first and a second probe connected to a volt meter into the receptacle and through any two of the first, second, third and fourth ports from outside of the enclosure;
wherein the inserting step results in direct electrical connection between the first and second probes and two of the lines L₁, L₂, L₃ and GRND associated with the respective ports to measure voltage therein and thereby provide an indication to a user of active voltage within the three-phase lines in the enclosure;
verifying voltage for each phase to phase combination of the L₁, L₂ and L₃ lines;
verifying voltage for each phase to ground combination of the L₁, L₂, L₃ and GRND lines;
wherein the first and second probe are each in direct physical contact with one of the lines L₁, L₂ and L₃ as a result of the inserting step;
wherein the indication of active voltage is provided without opening the enclosure;
monitoring an indicator mounted on an exterior of the enclosure and electrically coupled to the three-phase connection within the enclosure to thereby provide an indication of voltage being carried therein independent of the volt meter; and
verifying the operation of the volt meter at an electrical source other than any in the enclosure both prior to and subsequent to the inserting step.

22. The method of claim 21 further comprising:
prior to the isolating step,
(a) erecting a flash barrier proximate the enclosure;
(b) donning PPE;
(c) opening the enclosure via the panel;
(d) verifying voltage for each phase to phase combination of the L₁, L₂ and L₃ lines from within the enclosure;
(e) verifying voltage for each phase to ground combination of the L₁, L₂, L₃ and GRND lines from within the enclosure;
(f) closing the panel on the enclosure;
(g) monitoring the indicator to ascertain the voltage being carried by each of the L₁, L₂ and L₃lines;
(h) verifying voltage for each phase to phase combination of the L₁, L₂ and L₃ lines via the receptacle;
(i) verifying voltage for each phase to ground combination of the L₁, L₂, L₃ and GRND lines via the receptacle;
subsequent to the isolating step and while donning the PPE,
(a) opening the enclosure via the panel;
(b) verifying voltage for each phase to phase combination of the L₁, L₂ and L₃ lines from within the enclosure;
(c) verifying voltage for each phase to ground combination of the L₁, L₂, L₃ and GRND lines from within the enclosure; and
(d) closing the panel on the enclosure.
